(19) United States
(12) Patent Application Publication
(10) Pub. No.: US 2004/0085158 A1
(43) Pub. Date: May 6, 2004

(54) Dielectric component array

(76) Inventors: Joseph V. Van Hoyweghen III, Waterford, PA (US); Edward G. Sveda JR., North East, PA (US); Jeffrey D. Chereson, Erie, PA (US)

Correspondence Address: HODGSON RUSS LLP, ONE M & T PLAZA, SUITE 2000, BUFFALO, NY, 14203-2391, US

(21) Appl. No.: 10/692,123

(22) Filed: Oct. 23, 2003

Related U.S. Application Data
(60) Provisional application No. 60/420,530, filed on Oct. 23, 2002.

(51) Int. Cl. H03H 7/01

(52) U.S. Cl. 333/182

(57) ABSTRACT

The invention includes an electromagnetic filter for a feedthrough conductor, and a method of making such a filter. At least two dielectric components are supported from a first side of a substrate, such as a housing or a printed circuit board.

### CROSS-REFERENCE TO RELATED APPLICATION

This application claims the benefit of priority to U.S. provisional patent application serial No. 60/420,530, filed on Oct. 23, 2002, now pending.

### FIELD OF THE INVENTION

The present invention relates to electromagnetic filters and methods of providing electromagnetic filters.

### BACKGROUND OF THE INVENTION

In the prior art, it is known to use a discoidal capacitor circumferentially surrounding a feedthrough conductor. Such arrangements have cylindrical inner and outer electrode portions. The outer electrode portion is electrically connected to a ground plate, and an electrical connection is made between the inner electrode and the feedthrough conductor. As a result of using a discoidal capacitor, such arrangements are expensive and design changes are not easily accomodated.

### SUMMARY OF THE INVENTION

The invention includes an electromagnetic filter for a feedthrough conductor. In one embodiment of the invention, at least two dielectric components are supported from a first side of a substrate. The dielectric components may be capacitors. The first side is substantially planar, and the substrate also has a second side and a feedthrough surface. The feedthrough surface defines an orifice extending from the first side to the second side. Through the orifice extends a feedthrough conductor.

The invention also includes a method of providing an electromagnetic filter. In a method according to the invention, a substrate is provided. The substrate has a substantially planar first side, a second side and a feedthrough surface. The feedthrough surface defines an orifice extending from the first side to the second side. A feedthrough conductor is provide so that the feedthrough conductor extends through the orifice. A first dielectric component is supported from the first side and proximate to the feedthrough conductor. A second dielectric component is supported from the first side and proximate to the feedthrough conductor.

### BRIEF DESCRIPTION OF THE DRAWINGS

For a fuller understanding of the nature and objects of the invention, reference should be made to the following detailed description taken in conjunction with the accompanying drawings, in which:

FIG. 1 is a plan view schematic of a device according to the invention;

FIG. 2 is a partial perspective view of a device according to the invention;

FIG. 3 is a partial cross-sectional view of a device according to the invention;

FIG. 4 is a partial cross-sectional view of a device according to the invention;

FIG. 5 is a plan view schematic of a device according to the invention; and

FIG. 6 is a flow chart of a method according to the invention.

### DETAILED DESCRIPTION OF THE INVENTION

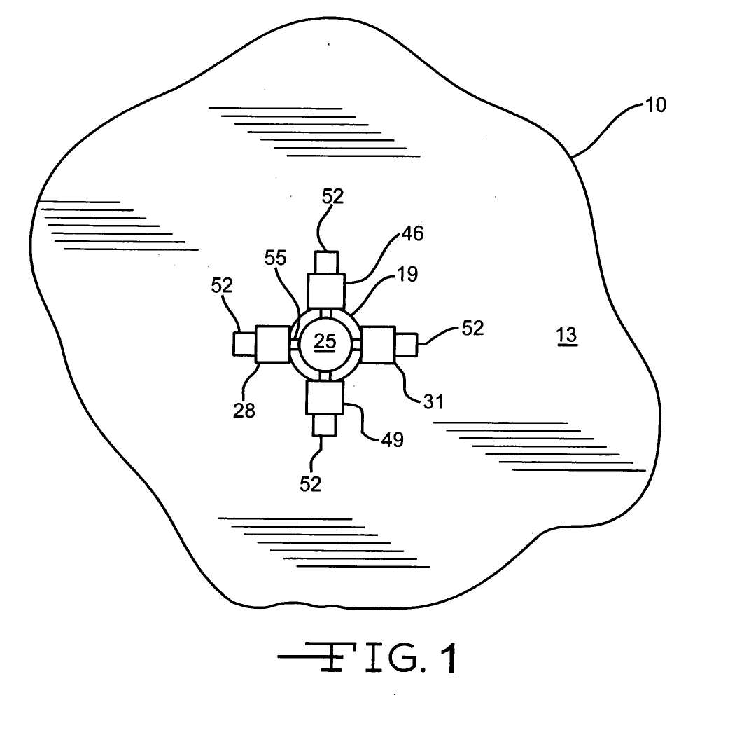

An embodiment of the invention may be made in the form of an electromagnetic filter. FIG. 1 is a schematic of such a filter. The filter may include a substrate 10 having a substantially planar first side 13. The substrate 10 may be a protective housing or a printed circuit board. The substrate 10 may have a second side 16 and a feedthrough surface 19. The feedthrough surface 19 may define an orifice 22 extending from the first side 13 to the second side 16. A feedthrough conductor 25 may extend through the orifice 22.

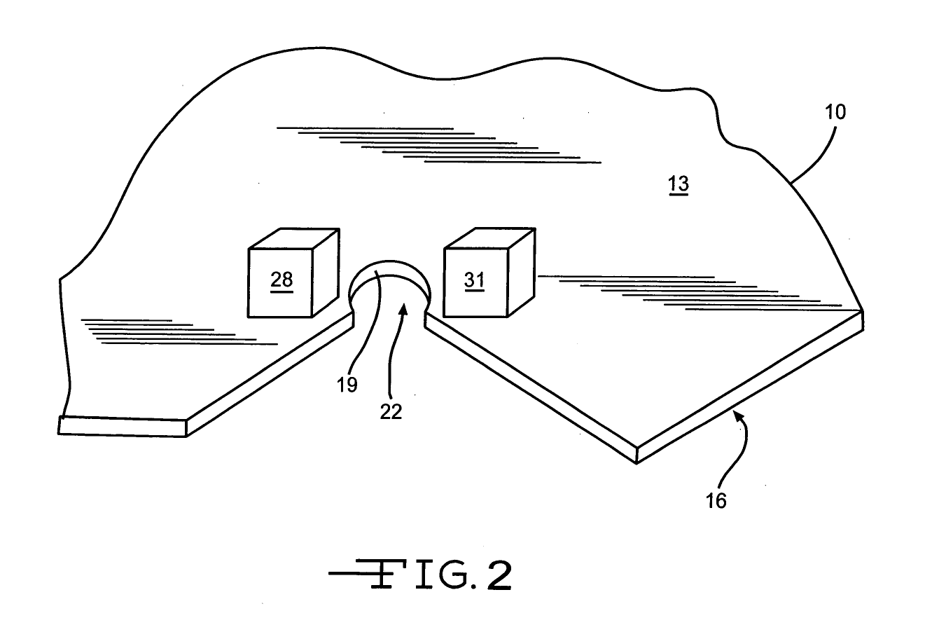

FIG. 2 shows a first dielectric component 28 being supported from the first side 13 of the substrate 10. The first dielectric component 28 may partially surround the conductor 25. A second dielectric component 31 may be supported from the first side 13 of the substrate 10, and the second dielectric component 31 may partially surround the conductor 25. Each of the dielectric components 28, 31 may be capacitors positioned to filter a signal carried by the feedthrough conductor 25.

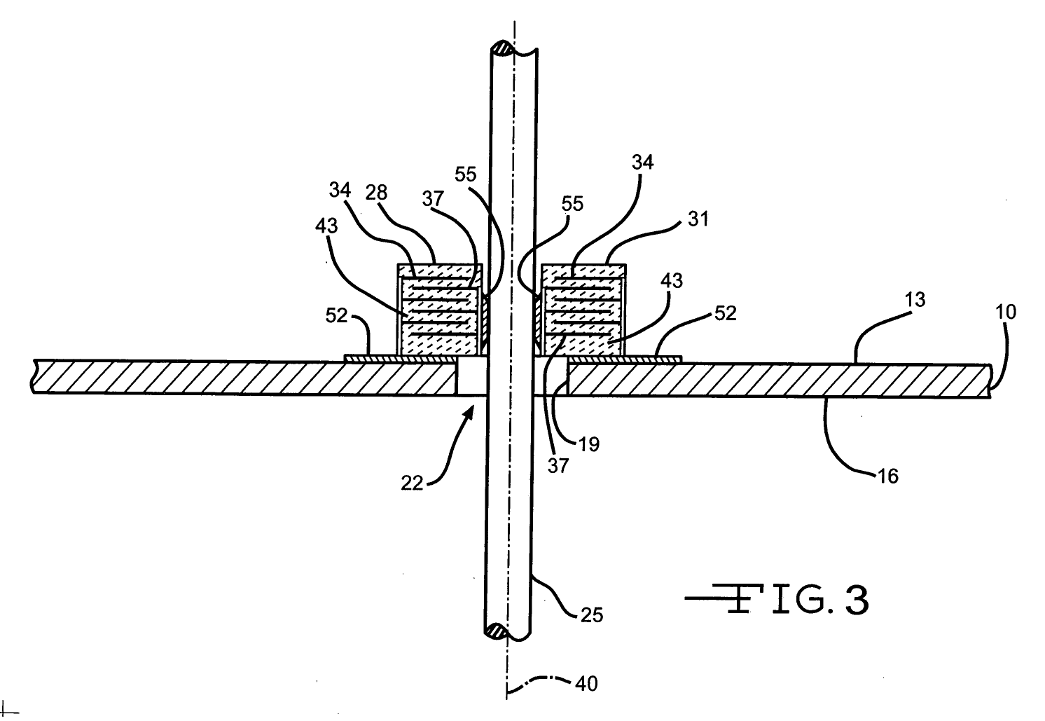

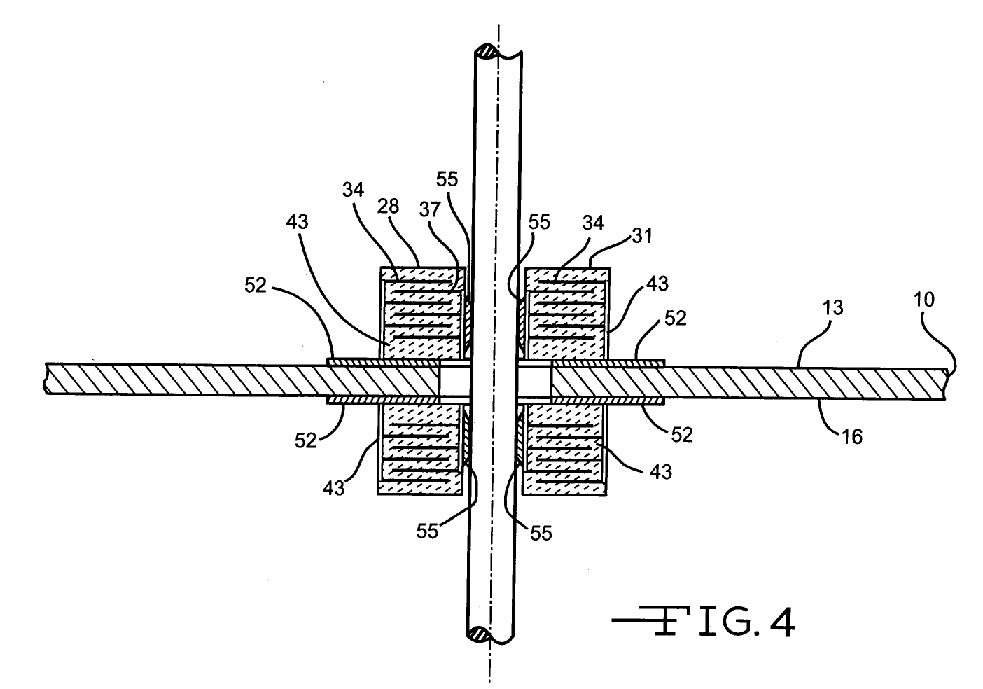

FIG. 3 shows a device according to the invention, which has been partially cross-sectioned to show certain features. For example, the capacitors may have plates 34, 37 oriented in a plane that is perpendicular to an axis 40 of the feedthrough conductor 25 and separated by a dielectric material 43. The dielectric material 43 may be barium-titanate, magnesium titanate, alumina, polyester, polyamide or a metal-oxide. As more discrete dielectric components 28, 31 are added around a conductor 25, the electromagnetic characteristics approach that of a discoidal capacitor. If the discrete dielectric components are chip capacitors supported from the same surface of the substrate, a reduction in cost may be realized since chip capacitors tend to be much less expensive than discoidal capacitors. Further, since chip capacitors may have the same or similar exterior dimensions but different electromagnetic characteristics, changes in the electromagnetic characteristics of a filter made according to the invention may be more easily accommodated. FIG. 4 is a device according to the invention in which the arrangement shown in FIG. 3 is made on both sides 13, 16 of the substrate 10.

One or more of the dielectric components 28, 31, 46, 49 may be electrically connected to a first conductive contact 52, which is associated with the first side 13. The first conductive contact 52 may be a trace on the substrate 10. The first conductive contact 52 may electrically connect one of the plates 34 to the substrate 10. Although the first conductive contact 52 of a dielectric component 28, 31, 46, 49 may be used to fix the dielectric component 28, 31, 46, 49 relative to the substrate 10, the first conductive contact 52 need not be used for that purpose. Each dielectric component 28, 31, 46, 49 may be packaged in such a way that the dielectric component 28, 31, 46, 49 has a side joined to the substrate 10 by a conductive or non-conductive material. For example, an adhesive may be used to join the dielectric component 28, 31, 46, 49 to the first side 13 so as to fix the dielectric component 28, 31, 46, 49 to the substrate 10.

Further, one or more of the dielectric components 28, 31, 46, 49 may have a second conductive contact 55 electrically connected to the feedthrough conductor 25. The second conductive contact 55 may be electrically connected to the other of the plates 37 to the feedthrough conductor 25. The second conductive contact 55 may be connected to the feedthrough conductor 25 at a location that is not within the orifice 22. With such an arrangement, the substrate 10 may be at a first electric potential and the conductor 25 may be at a second electric potential.

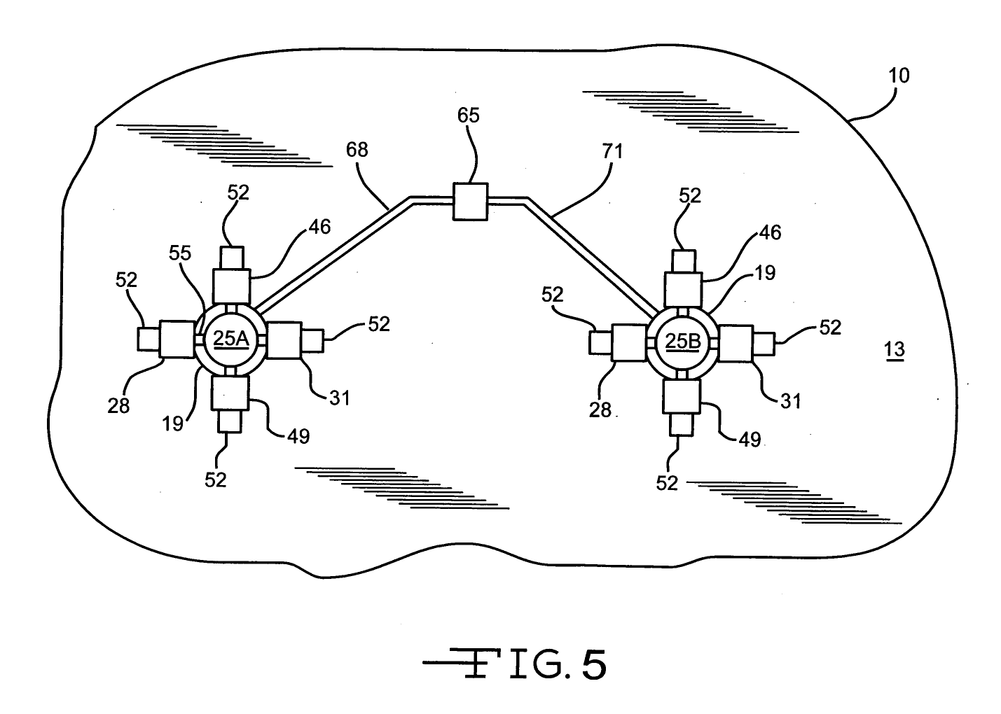

FIG. 5 shows an embodiment of the invention similar to that shown in FIG. 1. In FIG. 5, another capacitor 65 is electrically situated between two conductors 25A, 25B. Trace 68 electrically connects a first set of plates in the capacitor 65 to the conductor 25A. Trace 71 electrically connects a second set of plates in the capacitor 65 to conductor 25B. In this manner, additional electromagnetic filtering may be accomplished.

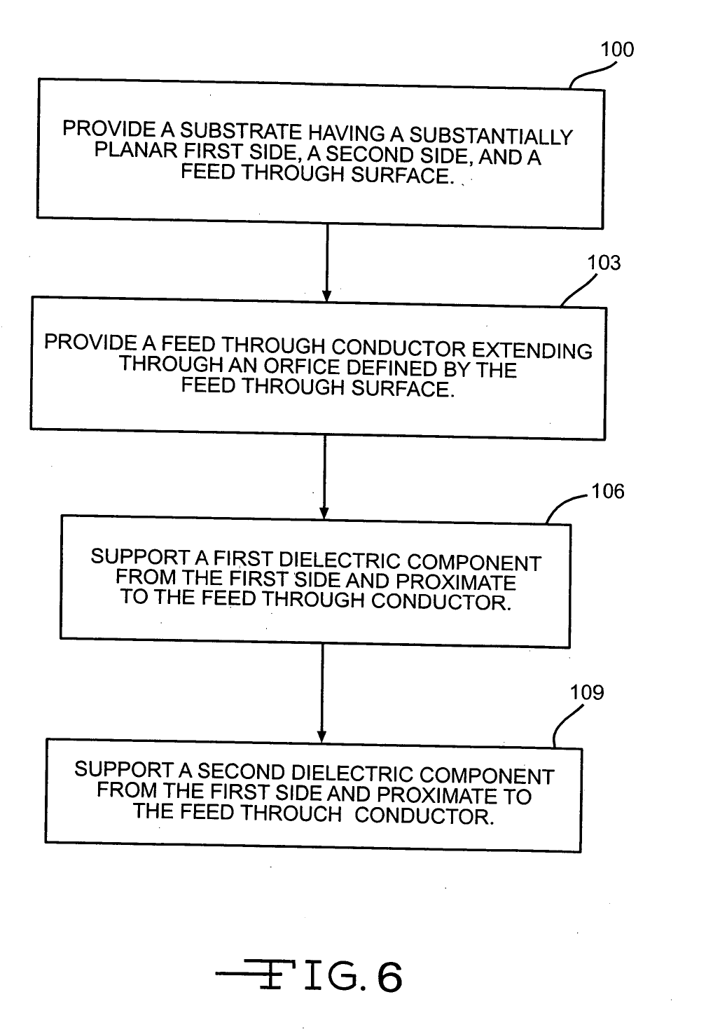

FIG. 6 is a flow chart of a method according to the invention. In an embodiment of the invention, a substrate is provided 100. The substrate has a substantially planar first side, a second side and a feedthrough surface. The feedthrough surface may define an orifice extending from the first side to the second side, and a feedthrough conductor may be provided 103 to extend through the orifice. A first dielectric component may be supported 106 from the first side and proximate to the feedthrough conductor, and the first dielectric component may be joined to the substrate, for example by soldering at least a portion of the first side to a conductive contact of the dielectric component. A second dielectric component may be supported 109 from the first side in the same fashion as the first dielectric component. Each of the dielectric components may be electrically connected to the feedthrough conductor, for example by soldering a conductive contact of each dielectric component to the feedthrough conductor.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. An electromagnetic filter comprising:
a substrate having a substantially planar first side, a second side and a feedthrough surface, the feedthrough surface defining an orifice extending from the first side to the second side;
a feedthrough conductor extending through the orifice;
a first dielectric component supported from the first side and partially surrounding the conductor; and
a second dielectric component supported from the first side and partially surrounding the conductor.

2. The filter of claim 1, wherein the first dielectric component is a capacitor.

3. The filter of claim 2, wherein the first dielectric component has conductive plates separated one from the other by a dielectric material.

4. The filter of claim 1, wherein the first dielectric component has a conductive contact electrically connected to the first side.

5. The filter of claim 4, wherein the first dielectric component has a first conductive plate electrically connected to the conductive contact, and a second conductive plate separated from the first conductive plate by a dielectric material and not electrically connected to the conductive contact.

6. The filter of claim 1, wherein the first dielectric component has a conductive contact electrically connected to the feedthrough conductor.

7. The filter of claim 6, wherein the conductive contact is not within the orifice.

8. The filter of claim 6, wherein the first dielectric component has a first conductive plate electrically connected to the conductive contact, and a second conductive plate separated from the first conductive plate by a dielectric material and not electrically connected to the conductive contact.

9. The filter of claim 1, wherein each dielectric component has a conductive contact electrically connected to the first side.

10. The filter of claim 9, wherein each dielectric component has a first conductive plate electrically connected to the conductive contact, and a second conductive plate separated from the first conductive plate by a dielectric material and not electrically connected to the conductive material.

11. The filter of claim 1, wherein each dielectric component has a conductive contact electrically connected to the feedthrough conductor.

12. The filter of claim 11, wherein the conductive contact is not within the orifice.

13. The filter of claim 11, wherein each dielectric component has a first conductive plate electrically connected to the conductive contact, and a second conductive plate separated from the first conductive plate by a dielectric material and not electrically connected to the conductive material.

14. The filter of claim 1, wherein the substrate is at a first electric potential and the conductor is at a second electric potential.

15. The filter of claim 1, wherein the first dielectric component has a side joined to the substrate by a conductive material.

16. The filter of claim 1, wherein the first dielectric component has a side joined to the feedthrough conductor by a conductive material.

17. The filter of claim 16, wherein the conductive material is not in the orifice.

18. A method of providing an electromagnetic filter, comprising:
provide a substrate having a substantially planar first side, a second side and a feedthrough surface, the feedthrough surface defining an orifice extending from the first side to the second side;
provide a feedthrough conductor extending through the orifice;
support a first dielectric component from the first side and proximate to the feedthrough conductor;
support a second dielectric component from the first side and proximate to the feedthrough conductor.

19. The method of claim 18, further comprising electrically connecting a conductive contact of each dielectric component to the substrate.

20. The method of claim 18, further comprising electrically connecting a conductive contact of each dielectric component to the feedthrough conductor.
